(19) United States
(12) Patent Application Publication
(10) Pub. No.: US 2016/0320445 A1
(43) Pub. Date: Nov. 3, 2016

(54) PROBELESS PARALLEL TEST SYSTEM AND METHOD FOR INTEGRATED CIRCUIT

(71) Applicant: NATIONAL TSING HUA UNIVERSITY, HSINCHU (TW)

(72) Inventors: Chrong-Jung LIN, Hsinchu City (TW); Ya-Chin KING, Hsinchu City (TW); Shi-Yu HUANG, Hsinchu City (TW)

(21) Appl. No.: 14/792,626

(22) Filed: Jul. 7, 2015

(30) Foreign Application Priority Data
Apr. 28, 2015 (TW) 104113553

(51) Int. Cl. G01R 31/28; G01R 31/317; G01R 31/3177

(52) U.S. Cl. CPC G01R 31/2851; G01R 31/3177; G01R 31/31724

(57) ABSTRACT

A probeless parallel test system for an integrated circuit (IC) includes an IC chip, a wireless power receiving module and a Build-In Self-Test (BIST) circuit. The wireless power receiving module is electrically connected to the IC chip. The BIST circuit is electrically connected to the wireless power receiving module and the IC chip. The wireless power receiving module, the BIST circuit and the IC chip are all formed on a wafer. The wireless power receiving module is used to provide electric power to the BIST circuit and the IC chip. When receiving the electric power, the IC chip executes a functional operation, and transmits an operation result to the BIST circuit for testing.

### RELATED APPLICATIONS

The application claims priority to Taiwan Application Serial Number 104113553, on Apr. 28, 2015 which is herein incorporated by reference.

### BACKGROUND

1. Technical Field

The present disclosure relates to a test system and a test method for an integrated circuit (IC). More particularly, the present disclosure relates to a probeless parallel test system and a probeless parallel test method for an integrated circuit.

2. Description of Related Art

Recently, the modern electronic devices have been gradually developed towards lightness, thinness, shortness and smallness. Furthermore, under miniaturization, such electronic devices still need to maintain the same or even higher operation efficiency. Moreover, with the advance of the manufacturing technology, the size of the electronic components in such electronic devices can be further reduced, and more IC chips can be formed in the same area, thus increasing the operation efficiency.

Although the IC manufacturing technology has been greatly developed, it is getting more difficult to form more IC chips in a much smaller area due to physical limitations. Therefore, the conventional planar ICs (2D IC or 2.5D IC) are not sufficient to meet use requirements. Accordingly 3D ICs are developed.

The fundamental thought of a 3D IC technology is to stack the IC chips layer by layer to construct a three-dimensional structure. One method for constructing the 3D IC is to build electric connections between layers of the stacked IC chips by using through silicon vias (TSVs). Because the TSVs are getting smaller with higher density, the 3D IC using the TSVs has become a mainstream in the field of IC manufacturing. For example, FIG. 1B is a schematic view showing a conventional 3D IC. In FIG. 1B, the 3D IC is constructed by stacking 2D ICs.

However, Regardless of the aforementioned 2D ICs or 3D ICs, it is a very critical to perform a functional test on each of the 2D ICs or each of the 3D ICs in the entire manufacturing process. When a conventional 2D IC is being tested, as shown in FIG. 1A, each of the probes 401 is required to contact each of the bonding pads 401 to provide electric power to the 2D IC, and reads out the test result to determine if each of the IC chips operates correctly. Since the 3D IC in FIG. 1B is constructed by stacking 2D ICs through TSVs, the test method of the 3D IC is similar to that in FIG. 1A, in which a probe test is performed on each of the bonding pads 402 of each layer of the IC chips, so as to determine if each of the IC chips operates correctly. With the advance of the photolithography technology, circuits with a unit area have become more and more complicated, and thus the conventional test method utilizing probes 401 has caused great inconvenience.

For reducing the usage amount of the bonding pads 402, a conventional IC test has used a large number of Build-In Self-Testing (BIST) circuits, thereby lowering the complexity of chip test.

Although the BIST circuits can reduce the usage amount of the bonding pads 402, a small number of bonding pads 402 are still required to provide the electric power to the BIST circuits and to read out the test results to determine if the circuits operate correctly. In this case, when the BIST circuits are applied to the 3D IC in FIG. 1B, the test process is still complicated. For example, the circuit functionality tests of the IC chips have to be performed in sequence, and then the IC chips having correct circuit functionality are picked out and stacked to from the 3D IC. The test time and the test cost will be increased with the number of the stacked layers of the 3D IC. Furthermore, the complicated structure of the 3D IC will dramatically increase the difficulty of the test process.

Accordingly, there is a need to develop a test system and a test method applicable to the 2D IC or 3D IC for reducing the difficulty level of the test, and saving test time and cost.

### SUMMARY

According to one aspect of the present disclosure, a probeless parallel test system for an integrated circuit (IC) is provided. The probeless parallel test system for an IC includes an IC chip, a wireless power receiving module and a Build-In Self-Test (BIST) circuit. The wireless power receiving module is electrically connected to the IC chip. The Build-In Self-Test (BIST) circuit is electrically connected to the wireless power receiving module and the IC chip. The wireless power receiving module, the BIST circuit and the IC chip are all formed on a wafer, and the wireless power receiving module is used to provide electric power to the BIST circuit and the IC chip, and after receiving the electric power from the wireless power receiving module, the IC chip executes as functional operation, and transmits an operation result to the BIST circuit for testing the correctness of the functional operation.

According to another aspect of the present disclosure, a probeless parallel test system for an integrated circuit (IC) is provided. The probeless parallel test system for an IC includes a wafer, a plurality of wireless power receiving modules and a plurality of Build-In Self-Test (BIST) circuits. A plurality of IC chips are formed on the wafer. The wireless power receiving modules are formed on the wafer, wherein the power receiving modules are electrically connected to the IC chips respectively. The Build-In Self-Test (BIST) circuits are formed on the wafer, wherein the BIST circuits are electrically connected to the wireless power receiving modules and the IC chips respectively. Wherein the wireless power receiving modules provide electric power to the BIST circuits and the IC chips in parallel synchronously, and after receiving the electric power, the IC chips execute corresponding functional operations, and transmit operation results to the BIST circuits for testing the correctness of the functional operations.

According to still another aspect of the present disclosure, a probeless parallel test method for an integrated circuit (IC) is provided. The probeless parallel test method for an IC includes: a plurality of IC chips, a plurality of wireless power receiving modules, a plurality of BIST circuits and a plurality of signal transmitting modules are formed on a wafer; a plurality of testing blocks are formed on the wafer, wherein each of the testing blocks comprises an IC chip, a wireless power receiving module, a BIST circuit and a signal transmitting module; a wireless power transmitting module is coupled with each of the wireless power receiving modules to provide electric power to each of the IC chips and each of the BIST circuits; functional operations of the IC chips are tested by the BIST circuits respectively; test results from the BIST circuits are stored in the signal transmitting modules respectively; the wafer is diced to form a plurality of separated testing blocks; in the testing blocks, the test results are outputted to a wireless signal reading module by the signal transmitting modules and a chip screening process is performed to determine if the IC chips in the testing blocks operate correctly in accordance with the test results read by the wireless signal reading module.

According to further another aspect of the present disclosure, a probeless parallel test method for an integrated circuit (IC) is provided. The probeless parallel test method for an IC includes: a plurality of IC chips, a plurality of wireless power receiving modules, a plurality of BIST circuits and a plurality of signal transmitting modules are formed on a water; a plurality of testing blocks are formed on the wafer, wherein each of the testing blocks comprises an IC chip, a wireless power receiving module, a BIST circuit and a signal transmitting module; a wireless power transmitting module is coupled with each of the wireless power receiving modules to provide electric power to each of the IC chips and each of the BIST circuits; functional operations of the IC chips are tested by the BIST circuits respectively; test results from the BIST circuits are stored in the signal transmitting module; in the testing block, the test results are shown by the signal transmitting modules; and a chip screening process is performed to determine if the IC chips in the testing blocks operates correctly.

### BRIEF DESCRIPTION OF THE DRAWINGS

The present disclosure can be more fully understood by reading the following detailed description of the embodiment, with reference made to the accompanying drawings as follows:

FIG. 1A is a schematic view showing a conventional 2D IC;

FIG. 1B is a schematic view showing a conventional 3D IC;

FIG. 2 is a schematic view showing a probeless parallel test system for an IC according to one embodiment of the present disclosure;

FIG. 3 is a schematic view showing the electric power transmission in FIG. 2;

FIG. 4 is a schematic view showing a probeless parallel test method for an IC according to another embodiment of the present disclosure; and

FIG. 5 is a schematic view showing a probeless parallel test method for an IC according to still another embodiment of the present disclosure.

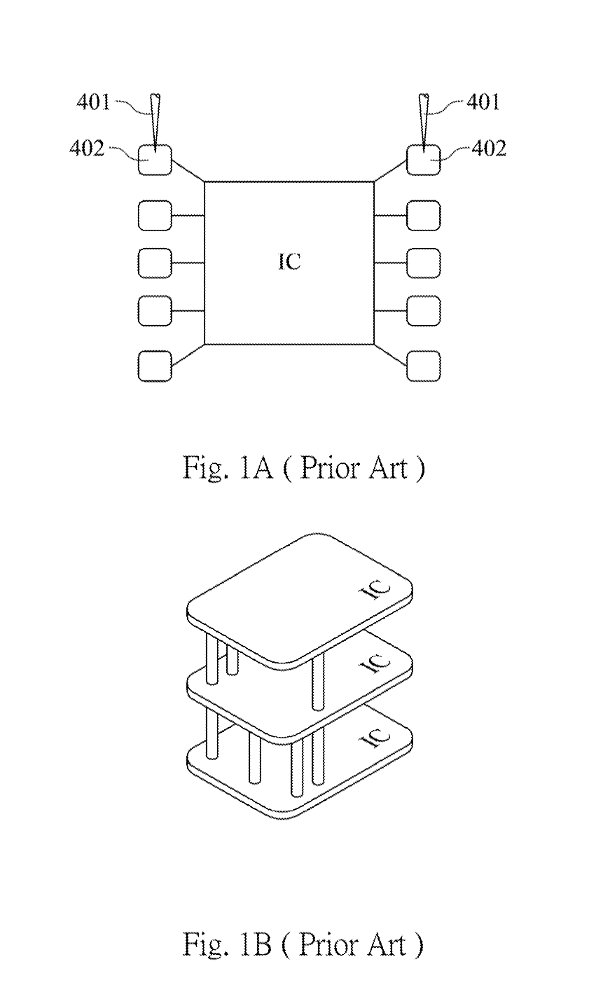

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

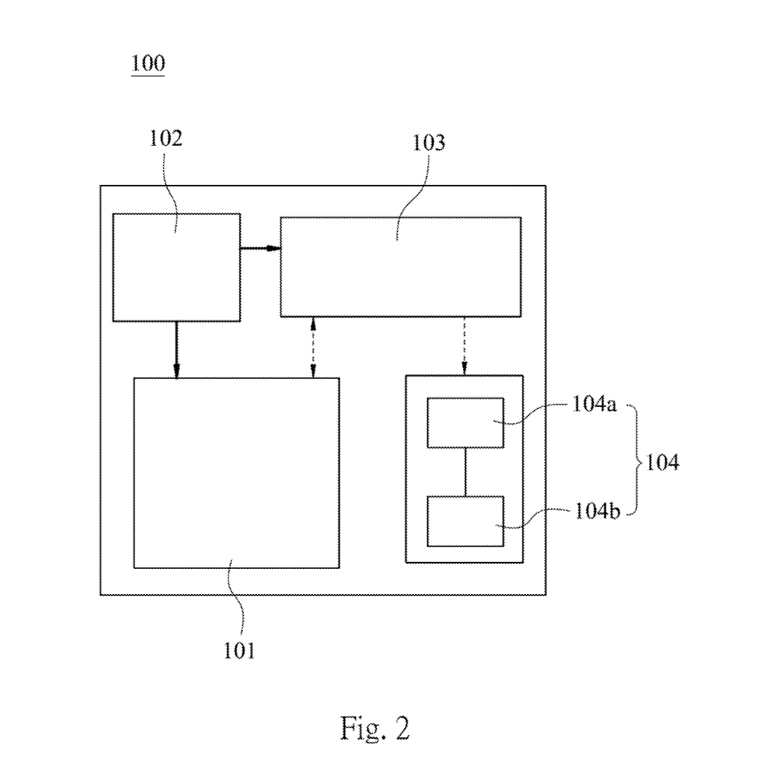

FIG. 2 is a schematic view showing a probeless parallel test system 100 for an IC according to one embodiment of the present disclosure.

A probeless parallel test system 100 includes an IC chip 101, a wireless power receiving module 102, a Build-in Self-Test (BIST) circuit 103 and a signal transmitting module 104. The wireless power receiving module 102 is electrically connected to the IC chip 101. The BIST circuit 103 is electrically connected to the wireless power receiving module 102 and the IC chip 101. The signal transmitting module 104 is electrically connected to the BIST circuit 103.

The wireless power receiving module 102, the BIST circuit 103 and the IC chip 101 are all formed on a water simultaneously. In one example, the signal transmitting module 104 can also be simultaneously formed on the wafer. The wireless power receiving module 102 provides electric power to the BIST circuit 103 and the IC chip 101. When the IC chip 101 receives the electric power provided by the wireless power receiving module 102, a functional operation is executed, and the operation result is transmitted to the BIST circuit 103 for testing. After the test is completed, the BIST circuit 103 transmits the test result to the signal transmitting module 104.

There may be various types of signal transmitting module 104 for transmitting the signal. In more detail. the signal transmitting module 104 includes a memory storage unit 104a and a signal transmitting unit 104b. The test result of the IC chip 101 from the BIST circuit 103 can he stored in the memory storage unit 104a, and the signal transmitting unit 104b can he used to transmit the test result. The memory storage unit 104a can be a non-volatile random-access memory (NVRAM), an electrically erasable programmable read-only memory (EEPROM), an erasable programmable read only memory (EPROM) or a flash memory.

The signal transmitting unit 104b can be a RFID transmitter, a lighting device or a sound device.

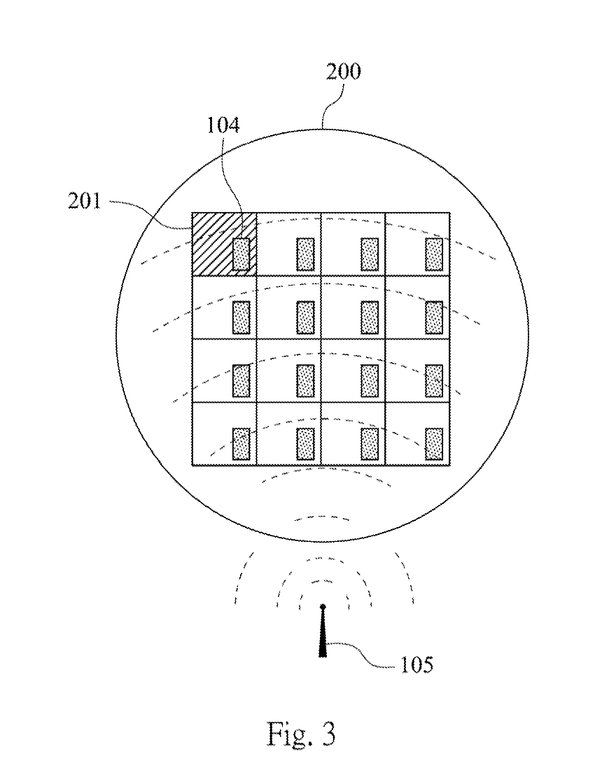

FIG. 3 is a schematic view showing the electric power transmission in FIG. 2. For achieving probeless test, the electric power in the probeless parallel test system 100 is provided wirelessly. In one example, as shown in FIG. 3, a wireless power transmitting module 105 is used external to a wafer 200. In the wafer 200, plural testing blocks 201 are formed. Each of the testing blocks 201 has an IC chip 101, a wireless power receiving module 102, a BIST circuit 103 and a signal transmitting module 104. The wireless power transmitting module 105 transmits energy to each of the wireless power receiving module 102 through magnetic induction, and thus each of the wireless power receiving modules 102 can generate electric power, and can provide the electric power to each of the IC chips 101 and each of the BIST circuits 103, such that each of the IC Chips 101 and each of the BIST circuits 103 can operate properly. The testing blocks 201 are simultaneously defined and formed when the IC chips 101 is manufactured.

In the aforementioned embodiments, no probes are required during the entire test process, and thus the test efficiency can be increased. Furthermore, through the magnetic induction, the wireless power transmitting module 105 can transfer energy to all of the wireless power receiving module 102, thereby achieving parallel and simultaneous tests.

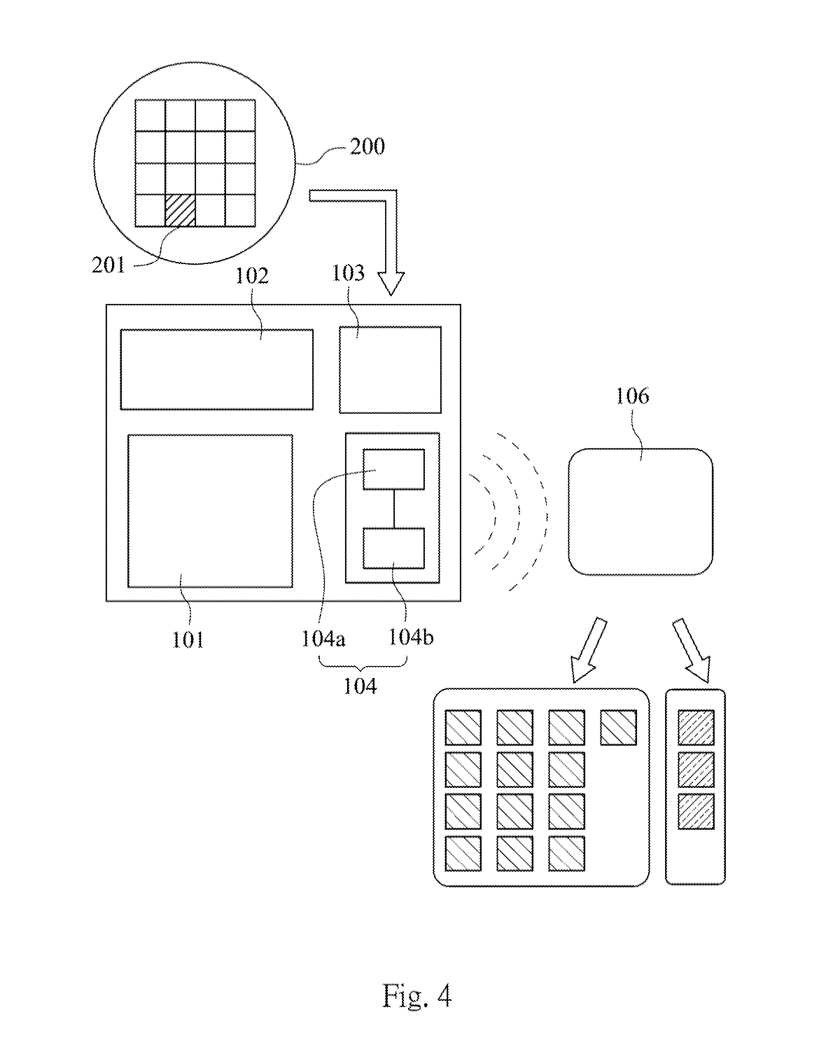

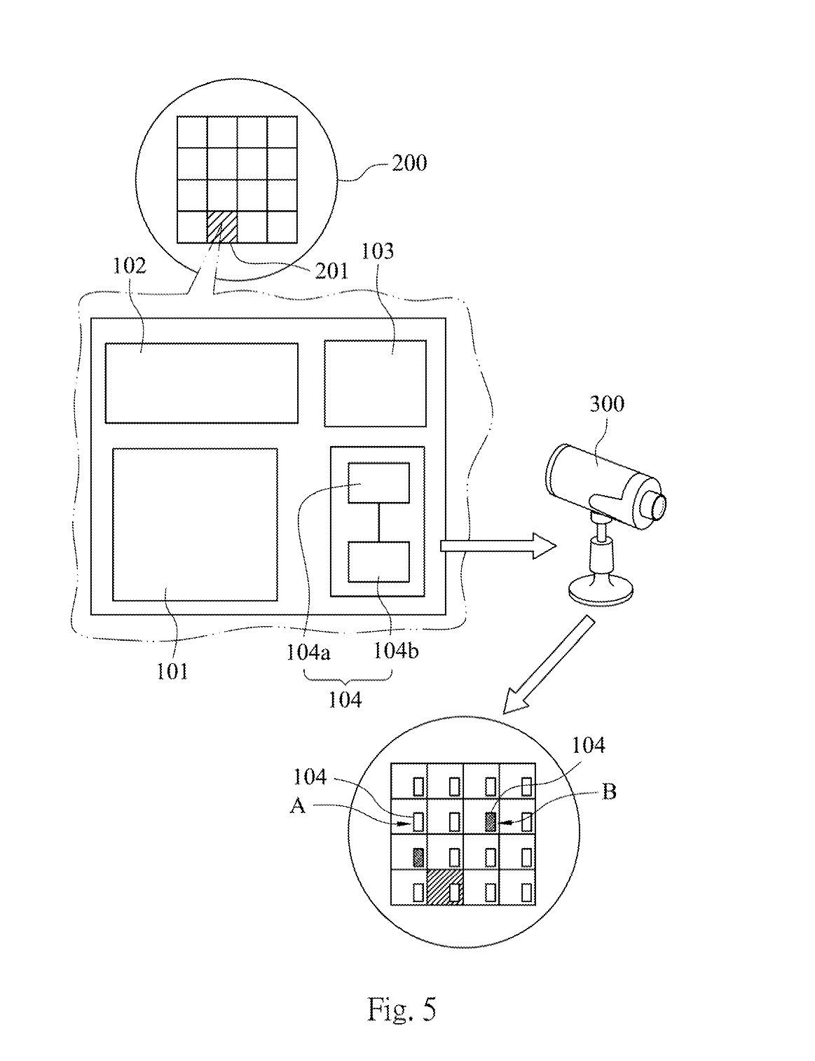

FIG. 4 is a schematic view showing a probeless parallel test method for an IC according to another embodiment of the present disclosure; and FIG. 5 is a schematic view showing a probeless parallel test method for an IC according to still another embodiment of the present disclosure.

In FIG. 4, an IC chip 101, a wireless power receiving module 102, a BIST circuit 103 and a signal transmitting module 104 are defined as a testing block 201. Accordingly, plural testing blocks 201 are formed when the wafer 200 is being fabricated. Then, the aforementioned test processes are performed, and the test result of each of the chips 101 is stored in the memory storage unit 104a of the signal transmitting module 104. Then, the wafer is diced to form the testing blocks 201. Then, a wireless signal reading module 106 is used to read the test result transmitted by the signal transmitting module 104 to determine if the IC chip 101 of each of the testing blocks 201 operates correctly, thereby distinguishing good IC chips from bad IC chips. The signal transmitting unit 104b of the signal transmitting module 104 can be a RFID transmitter. The RFID transmitter is used to assign an exclusive recognition ID to the test result of each of the ID chips 101, and transmits the test result. In one example, the wireless signal reading module 106 can be a REID reader, and thus the test result transmitted from the RFID transmitter (signal transmitting module 104) can be read out by the wireless signal reading module 106.

In FIG. 5, some steps are the same as those shown in FIG. 4. The signal transmitting unit 104b in FIG. 5 is a lighting device. Thereby, the dicing process in FIG. 4 is not performed, and the IC chip 101 of each of the testing blocks 201 which operates correctly (or incorrectly) is directly screened out from the wafer 200. In one example, an image sensing device 300 is used to sense the lighting signal shown by the signal transmitting unit 104b. If light intensity is classified as A, the IC chip 101 is marked as good; if light intensity is classified as B, meaning that the IC chip 101 is broken, and is marked as bad.

In FIG. 5, the operation state of each of the IC chips 101 can he shown by the signal transmitting unit 104b. The type of the signal transmitting unit 104b is not limited to a lighting device. For example, the signal transmitting unit 104b can also be a sound device. In this situation, different sounds can be used to indicate an IC chip 101 operates correctly or incorrectly. In this manner, a wafer map showing correctness of the operation of each IC chip 101 of the wafer 200 can be obtained without needing to dice the wafer 200, and a fail rate of each IC chip 101 can be obtained.

In sum, the probeless parallel test system 100 for an IC utilizes wireless power source and wireless signal transmission during the entire test process. Therefore, no probes are required, and the complexity of test can be reduced. Furthermore, a parallel and simultaneous test can be achieved, thus reducing test cost.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A probeless parallel test system for an integrated circuit (IC), the probeless parallel test system comprising:
an IC chip;
a wireless power receiving module electrically connected to the IC chip; and
a Build-In Self-Test (BIST) circuit electrically connected to the wireless power receiving module and the IC chip;
wherein the wireless power receiving module, the BIST circuit and the IC chip are all formed on as wafer, and the wireless power receiving module is used to provide electric power to the BIST circuit and the IC chip, and after receiving the electric power from the wireless power receiving module, the IC chip executes a functional operation, and transmits an operation result to the MST circuit for testing the correctness of the functional operation.

2. The probeless parallel test system of claim 1, further comprising a signal transmitting module electrically connected to the BIST circuit, wherein after testing the operation result, the BIST circuit transmits a test result to the signal transmitting module,

3. The probeless parallel test system of claim 2, wherein the signal transmitting module comprises a memory storage unit and a signal transmitting unit.

4. The probeless parallel test system of claim 3, wherein the memory storage unit is a non-volatile random-access memory (NVRAM).

5. The probeless parallel test system of claim 3, wherein the memory storage unit is an electrically erasable programmable read-only memory (EEPROM) an erasable programmable read only memory (EPROM) or a flash memory.

6. The probeless parallel test system of claim 3, wherein the signal transmitting unit is a radio frequency identification (RFID) transmitter.

7. The probeless parallel test system of claim 3, wherein the signal transmitting unit is a lighting device.

8. The probeless parallel test system of claim 3, the signal transmitting unit is a sound device.

9. The probeless parallel test system of claim 1, further comprising a wireless power transmitting module, wherein the wireless power transmitting module is coupled with the wireless power receiving module to provide the electric power to the IC chip and the BIST circuit.

10. The probeless parallel test system of claim 9, wherein the wireless power transmitting module is magnetically coupled with the wireless power receiving module.

11. The probeless parallel test system of claim 1, further comprising a wireless signal reading module to receive the test result transmitted from the signal transmitting module to identify the IC chip of which the functional operation functions correctly.

12. The probeless parallel test system of claim 11, wherein the wireless signal reading module is a RFID reader.

13. A probeless parallel test system for an IC, the probeless parallel test system comprising:
a wafer on which a plurality of IC chips are formed;
a plurality of wireless power receiving modules formed on the wafer, wherein the over receiving modules are electrically connected to the IC chips respectively; and
a plurality of Build-In Self-Test (BIST) circuits formed on the wafer, wherein the BIST circuits are electrically connected to the wireless power receiving modules and the IC chips respectively;
wherein the wireless power receiving modules provide electric power to the BIST circuits and the IC chips in parallel synchronously, and after receiving the electric power, the IC chips execute corresponding functional operations, and transmit operation results to the BIST circuits for testing the correctness of the functional operations.

14. The probeless parallel test system of claim 13, further comprising a plurality of signal transmitting modules, wherein the signal transmitting modules are electrically connected to the MST circuits respectively; after testing the operation results, the BIST circuits transmit test results of the IC chips to the signal transmitting modules respectively.

15. The probeless parallel test system of claim 13, further comprising a wireless power transmitting module, wherein the wireless power transmitting module is coupled with each of the wireless power receiving module to provide the electric power to each of the IC chips and each of the BIST circuits.

16. The probeless parallel test system of claim 13, further comprising a wireless signal reading module configured to receive the test results transmitted from the signal transmitting modules to identify the IC chips of which the functional operations function correctly.

17. A probeless parallel test method for an IC, the probeless parallel test method comprising:
forming a plurality of IC chips, a plurality of wireless power receiving modules, a plurality of BIST circuits and a plurality of signal transmitting modules on a wafer;
forming, a plurality of testing blocks on the wafer, wherein each of the testing blocks comprises an IC chip, a wireless power receiving module, a BIST circuit and a signal transmitting module;
coupling a wireless power transmitting module with each of the wireless power receiving modules to provide electric power to each of the IC chips and each of the BIST circuits;
testing functional operations of the IC chips by the BIST circuits respectively;
storing test results from the MST circuits in the signal transmitting modules respectively;
dicing the wafer to form a plurality of separated testing blocks;
in the testing blocks, outputting the test results to a wireless signal reading module by the signal transmitting modules and performing a chip screening process to determine if the IC chips in the testing blocks operate correctly in accordance with the test results read by the wireless signal reading module.

18. The probeless parallel test method of claim 17, wherein the signal transmitting module comprises a memory storage unit and a signal transmitting unit.

19. The probeless parallel test method of claim 18, wherein each of the signal transmitting units is a RFID transmitter.

20. The probeless parallel test method of claim 17, wherein the wireless signal reading module is a RFID reader.

21. A probeless parallel test method for an IC, the probeless parallel test method comprising:
forming a plurality of IC chips, a plurality of wireless power receiving modules, a plurality of BIST circuits and a plurality of signal transmitting modules on a wafer;
forming a plurality of testing blocks on the wafer, wherein each of the testing blocks comprises an IC chip, a wireless power receiving module, a BIST circuit and a signal transmitting module;
coupling a wireless power transmitting module with each of the wireless power receiving modules to provide electric power to each of the IC chips and each of the BIST circuits;
testing functional operations of the IC chips by the BIST circuits respectively;
storing test results from the BIST circuits in the signal transmitting module; and
in the testing blocks, showing the test results by the signal transmitting modules; and
performing a chip screening process to determine if the IC chips in the testing blocks operates correctly.

22. The probeless parallel test method of claim 21, wherein each of the signal transmitting modules comprises a memory storage unit and a signal transmitting unit.

23. The probeless parallel test method of claim 22, wherein each of the signal transmitting units is a lighting device or a sound device.
